(19) United States
(12) Patent Application Publication
(10) Pub. No.: US 2025/0143146 A1
(43) Pub. Date: May 1, 2025

(54) PROTECTIVE FILM, DISPLAY DEVICE INCLUDING THE PROTECTIVE FILM, AND METHOD OF MANUFACTURING THE DISPLAY DEVICE

(71) Applicants: Samsung Display Co., Ltd., Yongin-Si (KR); Research & Business Foundation SUNGKYUNKWAN UNIVERSITY, Suwon-si (KR)

(72) Inventors: SEUNGWOOK KWON, Yongin-si (KR); Ji Won SUK, Suwon-si (KR); Hyeon-Jong LEE, Suwon-si (KR); WOO YONG SUNG, Yongin-si (KR); SEUNGYONG SONG, Yongin-si (KR); HEECHANG YOON, Yongin-si (KR); JEONGSEOK LEE, Yongin-si (KR)

(21) Appl. No.: 18/919,432

(22) Filed: Oct. 18, 2024

(30) Foreign Application Priority Data
Oct. 31, 2023 (KR) 10-2023-0148374

(51) Int. Cl. H10K 59/80; H10K 59/12; H10K 102/00

(52) U.S. Cl. CPC H10K 59/873; H10K 59/1201; H10K 2102/311

(57) ABSTRACT

A protective film included in the display device is manufactured by preparing a graphene oxide particle in powdered state, adjusting a size of the graphene oxide particle to achieve a preselected dispersibility in the carbon nanocomposite, and mixing the size-adjusted graphene oxide particle with a photocurable resin.

This application claims priority to Korean Patent Application No. 10-2023-0148374 filed on Oct. 31, 2023 and all the benefits accruing therefrom under 35 U.S.C. § 119, the content of which is herein incorporated by reference.

### BACKGROUND

### Field

Implementations of the inventive concept relate generally to a protective film, a display device including the protective film, and method of manufacturing the display device.

### Background

Display devices can be divided into rigid display devices and flexible display devices. Flexible display devices include bendable display devices, curved display devices, foldable display devices, and a rollable display devices, among others.

The flexible display device may include a flexible substrate (e.g., a plastic substrate) and a protective film supporting the flexible substrate. The protective film is made of plastic and is generally implemented as PET film.

### SUMMARY

Embodiments provide a protective film.

Embodiments provide a display device including the protective film.

Embodiments provide a method of manufacturing the display device.

A protective film according to an embodiment may include a photocurable resin, and a carbon nanocomposite including a graphene oxide particle having a particle size that is adjusted to achieve a preselected dispersibility in the carbon nanocomposite.

In an embodiment, a size of the graphene oxide particle may be about 0.1 μm to about 2 μm.

In an embodiment, a weight ratio of the carbon nanocomposite may be about 0.05 wt % to about 20 wt %.

In an embodiment, the carbon nanocomposite may further include carbon black.

In an embodiment, the photocurable resin may be cured by light and may have a viscosity of about 10 cPS to about 500 cPS.

A display device according to an embodiment may include a lower protective film including a photocurable resin and a carbon nanocomposite, wherein the carbon nanocomposite includes a graphene oxide particle, a flexible substrate disposed on the lower protective film, a transistor layer disposed on the flexible substrate, and an emission layer disposed on the transistor layer.

In an embodiment, a size of the graphene oxide particle may be about 0.1 μm to about 2 μm.

In an embodiment, the flexible substrate may include a flat area having a first flat area and a second flat area, a bending area between the first flat area and the second flat area. The lower protective film may overlap the flat area and may not overlap the bending area.

In an embodiment, the display device may further include a plurality of glass patterns disposed under the flexible substrate, the lower protective film may cover the glass patterns.

A method of manufacturing a display device according to an embodiment may include forming a protective film, forming a display panel on a flexible substrate, and forming the protective film under the flexible substrate. The forming the protective film may include preparing a graphene oxide particle in powdered stat, adjusting a size of the graphene oxide particle, and forming a composite ink by mixing the size-adjusted graphene oxide particle with adjusted size with a photocurable resin.

In an embodiment, a size of the graphene oxide particle with adjusted size may be about 0.1 μm to about 2 μm.

In an embodiment, a size of the graphene oxide particle in powdered state may be about 20 μm to about 40 μm.

In an embodiment, the method may further include dispersing the powdered graphene oxide particle in water.

In an embodiment, a size of the graphene oxide particle dispersed in water may be about 5 μm to about 15 μm.

In an embodiment, a size of the graphene oxide particle may be adjusted by sonication of the graphene oxide particle.

In an embodiment, the method may further include removing water from the size-adjusted graphene oxide particle.

In an embodiment, the protective film may include a first lower protective film and a second lower protective film which have a different physical property from each other, the first lower protective film may be formed by ejecting a first composite ink from a first inkjet head, and the second lower protective film may be formed by ejecting a second composite ink having different physical properties from the first composite ink from a second inkjet head.

In an embodiment, the first lower protective film and the second lower protective film may overlap each other with the flexible substrate in a bent state.

Therefore, a protective film according to embodiments of the present invention may include a polymer resin (for example, an acrylate-based photocurable resin) and a graphene oxide (GO) particle whose particle size is adjusted. The size of the graphene oxide particle may be adjusted through a sonication process (e.g., tip-sonication process and/or bath-sonication process), and then dispersibility in the polymer resin can be improved through a freeze-drying process. As the protective film includes both an organic material (e.g., a polymer resin) and an inorganic material (e.g., a graphene oxide particle), the heat dissipation function of the protective film can be improved and the strength of the protective film can be improved.

In addition, the protective film may be formed through an inkjet printing process using ink. Accordingly, protective films of various structures may be appropriately formed as needed. For example, the shape of the protective film may be formed to correspond to the pattern of the patterned flexible substrate. In addition, as the physical properties of the composite ink are manufactured differently, the protective film can be formed in a stacked structure, or the protective film can be formed separately for each region.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a cross-sectional view illustrating a display device according to an embodiment of the present invention.

FIG. 2 is a cross-sectional view illustrating a display panel and a sensing layer included in the display device of FIG. 1.

FIG. 3 is a flowchart illustrating a method of manufacturing a protective film included in the display device of FIG. 1.

FIGS. 4, 5, 6, 7, and 8 are diagrams illustrating the method of FIG. 3.

FIGS. 9 to 22 are diagrams illustrating examples in which the protective film manufactured using the method of FIG. 3 is applied.

### DETAILED DESCRIPTION

Illustrative, non-limiting embodiments will be more clearly understood from the following detailed description in conjunction with the accompanying drawings.

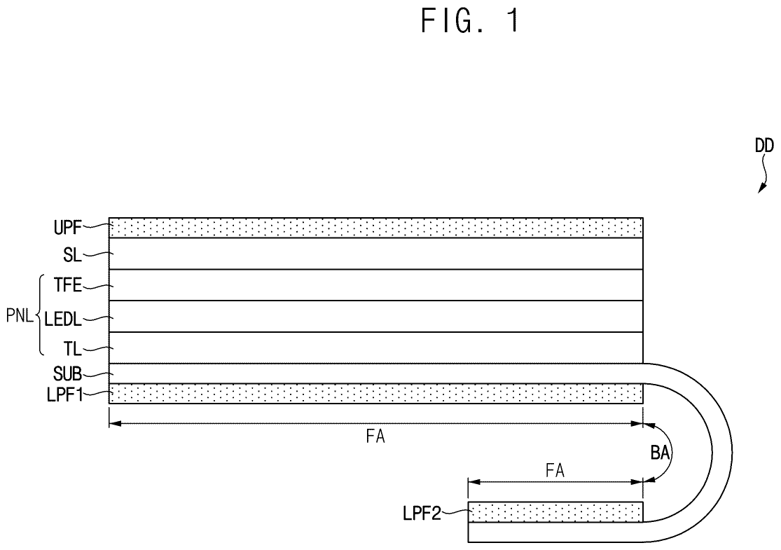

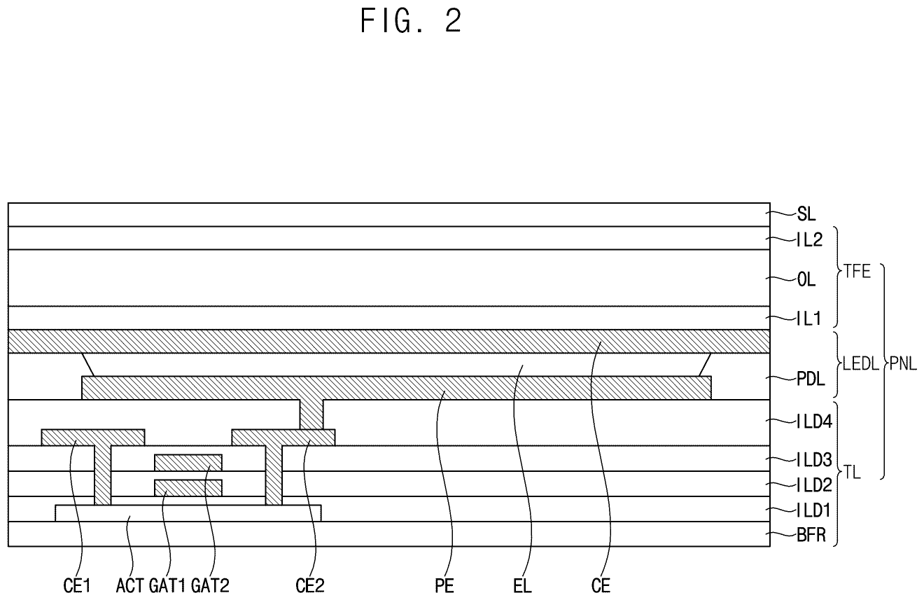

FIG. 1 is a cross-sectional view illustrating a display device according to an embodiment of the present invention. FIG. 2 is a cross-sectional view illustrating a display panel and a sensing layer included in the display device of FIG. 1.

Referring to FIG. 1, a display device DD according to an embodiment of the present invention may include a first lower protective film LPF1, a second lower protective film LPF2, a flexible substrate SUB, a display panel PNL, a sensing layer SL, and an upper protective film UPF. The display panel PNL may include a transistor layer TL, an emission layer LEDL, and a thin film encapsulation layer TFE.

The flexible substrate SUB may include a transparent or opaque material. In addition, the flexible substrate SUB may be formed of a flexible material. In an embodiment, examples of materials that can be used as the flexible substrate SUB may include ultra-thin tempered glass (UTG), glass, quartz, and plastic. These can be used alone or in combination with each other. In addition, the flexible substrate SUB may be composed of a single layer or multiple layers in combination with each other.

In an embodiment, the flexible substrate SUB may be divided into a flat area FA and a bending area BA, and the bending area BA may be bent from the flat area FA.

The first lower protective film LPF1 and the second lower protective film LPF2 may be disposed under the flexible substrate SUB and may overlap the flat area FA. The first and second lower protective films LPF1 and LPF2 may support the flexible substrate SUB.

Referring to FIG. 1 and FIG. 2, the transistor layer TL may be disposed on the flexible substrate SUB. The transistor layer TL may include a buffer layer BFR, an active pattern ACT, a first insulating layer ILD1, a first gate electrode GAT1, a second insulating layer ILD2, a second gate electrode GAT2, a third insulating layer ILD3, a first connection electrode CE1, a second connection electrode CE2, and a fourth insulating layer ILD4.

The buffer layer BFR may be disposed on the flexible substrate SUB. In an embodiment, the buffer layer BFR may be formed of an inorganic insulating material. Examples of materials that can be used as the inorganic insulating material may include silicon oxide, silicon nitride, and silicon oxynitride. These can be used alone or in combination with each other. The buffer layer BFR may prevent metal atoms, atoms, or impurities from diffusing from the flexible substrate SUB to the active pattern ACT. In addition, the buffer layer BFR may control the rate of heat provision during the crystallization process to form the active pattern ACT.

The active pattern ACT may be disposed on the buffer layer BFR. In an embodiment, the active pattern ACT may be formed of a silicon semiconductor material or an oxide semiconductor material. Examples of the silicon semiconductor material that can be used as the active pattern ACT may include amorphous silicon and polycrystalline silicon. Examples of the oxide semiconductor material that can be used as the active pattern ACT may include InGaZnO (IGZO), InSnZnO (ITZO), etc. In addition, the oxide semiconductor material may further include indium (In), gallium (Ga), tin (Sn), zirconium (Zr), vanadium (V), hafnium (Hf), cadmium (Cd), germanium (Ge), and chromium (Cr), titanium (Ti), and zinc (Zn). These can be used alone or in combination with each other.

The first insulating layer ILD1 may cover the active pattern ACT and may be disposed on the buffer layer BFR. In an embodiment, the first insulating layer ILD1 may be formed of an insulating material. Examples of insulating materials that can be used as the first insulating layer ILD1 may include silicon oxide, silicon nitride, and silicon oxynitride. These can be used alone or in combination with each other.

The first gate electrode GAT1 may be disposed on the first insulating layer ILD1. In an embodiment, the first gate electrode GAT1 may be formed of metal, alloy, conductive metal oxide, transparent conductive material, etc. Examples of materials that can be used as the first gate electrode GAT1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc. These can be used alone or in combination with each other.

The second insulating layer ILD2 may be disposed on the first insulating layer ILD1. The second insulating layer ILD2 may cover the first gate electrode GAT1. In an embodiment, the second insulating layer ILD2 may be formed of an insulating material.

The second gate electrode GAT2 may be disposed on the second insulating layer ILD2. In an embodiment, the second gate electrode GAT2 may be formed of metal, alloy, conductive metal oxide, transparent conductive material, etc.

The third insulating layer ILD3 may be disposed on the second insulating layer ILD2. The third insulating layer ILD3 may cover the second gate electrode GAT2. In an embodiment, the third insulating layer ILD3 may be formed of an insulating material.

The first and second connection electrodes CE1 and CE2 may be disposed on the third insulating layer ILD3 and may be connected to the active pattern ACT. In an embodiment, the first and second connection electrodes CE1 and CE2 may be formed of metal, alloy, conductive metal oxide, transparent conductive material, etc.

The fourth insulating layer ILD4 may be disposed on the third insulating layer ILD3. The fourth insulating layer ILD4 may cover the first and second connection electrodes CE1 and CE2. In an embodiment, the fourth insulating layer ILD4 may be formed of an insulating material. Examples of organic materials that can be used as the fourth insulating layer ILD4 may include photoresist, polyacrylic resin, polyimide resin, and acrylic resin. These can be used alone or in combination with each other.

The emission layer LEDL may include a pixel electrode PE, a pixel defining layer PDL, an organic emission layer EL, and a common electrode CE.

The pixel electrode PE may be disposed on the fourth insulating layer ILD4 and may be connected to the second connection electrode CE2. In an embodiment, the pixel electrode PE may be formed of metal, alloy, conductive metal oxide, transparent conductive material, etc.

The pixel defining layer PDL may be disposed on the pixel electrode PE and may cover the ends of the pixel electrode PE. In some embodiments, the pixel defining layer PDL may be formed of an organic material. Examples of organic materials that can be used as the pixel defining layer PDL may include photoresist, polyacrylic resin, polyimide resin, and acrylic resin. These can be used alone or in combination with each other.

The organic emission layer EL may be disposed on the pixel electrode PE, and the common electrode CE may be disposed on the organic emission layer EL. The organic emission layer EL may emit light based on the voltage difference between the pixel electrode PE and the common electrode CE.

The thin film encapsulation layer TFE may include a first inorganic layer IL1, an organic layer OL, and a second inorganic layer IL2. The thin film encapsulation layer TFE may protect the organic emission layer EL from moisture and/or oxygen.

The first inorganic layer IL1 may be disposed on the common electrode CE. In an embodiment, the first inorganic layer IL1 may be formed of an inorganic insulating material. Examples of inorganic insulating materials that can be used as the first inorganic layer IL1 may include silicon oxide, silicon nitride, and silicon oxynitride. These can be used alone or in combination with each other.

The organic layer OL may be disposed on the first inorganic layer IL1. In some embodiments, the organic layer OL may be formed of an organic insulating material. Examples of organic insulating materials that can be used as the organic layer OL may include photoresist, polyacrylic resin, polyimide resin, and acrylic resin. These can be used alone or in combination with each other.

The second inorganic layer IL2 may be disposed on the organic layer OL. In an embodiment, the second inorganic layer IL2 may be formed of an inorganic insulating material.

The sensing layer SL may be disposed on the second inorganic layer IL2. In an embodiment, the sensing layer SL may be a touch panel that senses the user's touch.

Referring again to FIG. 1, the upper protective film UPF may be disposed on the sensing layer SL. The upper protective film UPF may protect the sensing layer SL, the display panel PNL, and any other layers in the display device DD from external shock.

In an embodiment, the first lower protective film LPF1, the second lower protective film LPF2, and the upper protective film UPF may include a polymer resin and a carbon nanocomposite.

In an embodiment, the polymer resin may include a photocurable resin that is cured by light. For example, the photocurable resin may include an organic monomer containing an acrylate functional group. In addition, the photocurable resin may have a relatively low viscosity, for example, about 10 cPS to about 500 cPS. Accordingly, the first lower protective film LPF1, the second lower protective film LPF2, and the upper protective film UPF may be smoothly formed through an inkjet printing process.

In some embodiments, the carbon nanocomposite may include a graphene oxide particle (GO), a reduced graphene oxide particle (rGO), a carbon black, a non-oxidized graphene, and a carbon nanotube (CNT), etc.

In some embodiments, the graphene oxide particle may have a size of about 0.1 μm to about 2 μm and may have a plate-like structure. Preferably, the graphene oxide particle may have a size of about 0.3 μm. In addition, a weight ratio of the carbon nanocomposite may be about 0.05 wt % to about 20 wt %, and preferably about 10 wt %. By adjusting the size of the graphene oxide particle and the weight ratio of the carbon nanocomposite, its dispersibility in the carbon nanocomposite in the photocurable resin may be improved. However, the size and weight ratio of the graphene oxide particle are not limited to the above-mentioned values, and may be appropriately adjusted as needed considering the diameter of the inkjet nozzle, the dispersibility of the carbon nanocomposite, etc.

Meanwhile, although it has been described that the first lower protective film LPF1, the second lower protective film LPF2, and the upper protective film UPF include the same material, the present invention is not limited thereto. For example, the upper protective film UPF may be implemented as a plastic film such as PET.

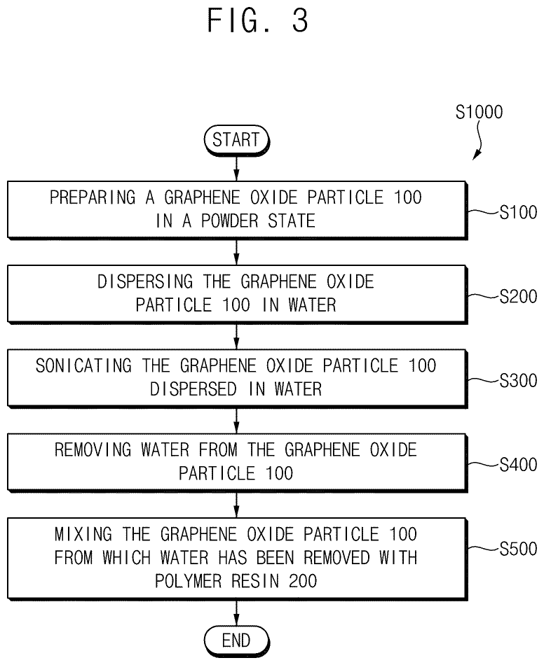

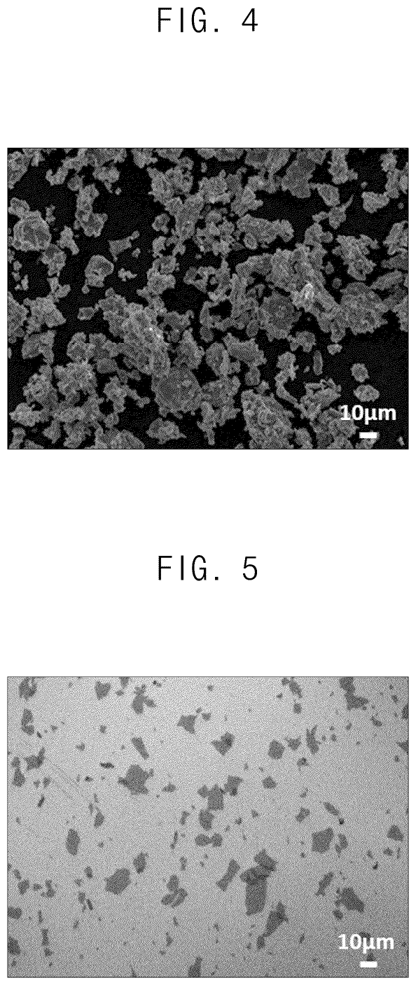

FIG. 3 is a flowchart illustrating a method of manufacturing a protective film included in the display device of FIG. 1. FIGS. 4, 5, 6, 7, and 8 are diagrams illustrating the method of FIG. 3.

Referring to FIG. 3, a method (S1000) of manufacturing a protective film (e.g., the first lower protective film LPF1, the second lower protective film LPF2, and the upper protective film UPF), preparing a graphene oxide particle 100 in a powdered state (S100), dispersing the graphene oxide particle 100 in water (S200), sonicating the graphene oxide particle 100 dispersed in water (S300), removing water from the sonicated graphene oxide particle 100 (S400), and mixing the graphene oxide particle 100 from which water has been removed with polymer resin 200.

The display device DD described above may be manufactured by forming the display panel PNL on the flexible substrate SUB and forming the manufactured protective film on the lower surface of the flexible substrate SUB.

Referring to FIGS. 3 and 4, the graphene oxide particle 100 in powdered state may be prepared (S100). For example, the graphene oxide particle 100 may have a size of about 20 μm to about 40 μm, and specifically, may have a size of about 30 μm.

Referring to FIGS. 3 and 5, the graphene oxide particle 100 may be dispersed in water (S200). For example, the graphene oxide particle 100 dispersed in water may have a size of about 5 μm to about 15 μm, and specifically may have a size of about 10 μm.

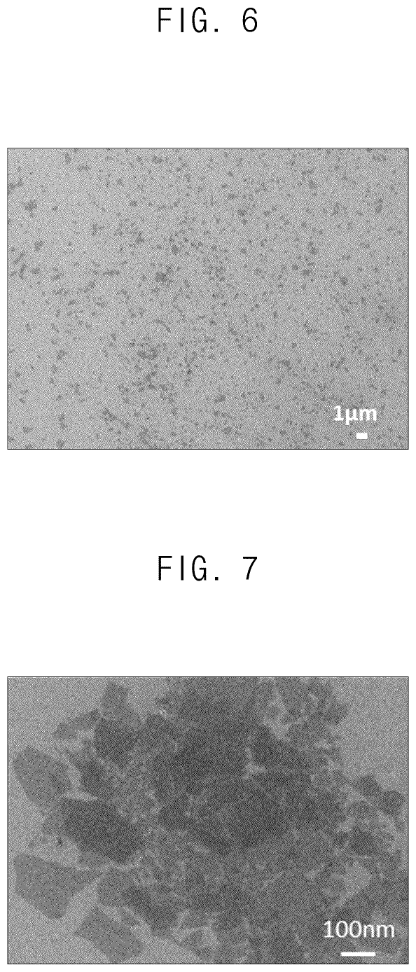

Referring to FIGS. 3 and 6, the size of the graphene oxide particle 100 may be from about 0.1 μm to about 2 μm (S300). In some embodiments, the size of the graphene oxide particle 100 may be adjusted by sonication of the graphene oxide particle 100. For example, with graphene oxide particle 100 dispersed in water, a bath-sonication process may be performed for about 1 hour, and a tip-sonication process may be performed for about 1 hour. In another example, a tip-sonication process may be performed for about 2 hours on the graphene oxide particle 100 dispersed in water.

However, the method of adjusting the size of the graphene oxide particle 100 is not limited to what is explicitly described herein, and various physical/chemical processes can be applied to achieve a desired size of the graphene oxide particle 100.

Referring to FIGS. 3 and 7, water in the graphene oxide particle 100 may be removed after size adjustment (S400). In some embodiments, water may be removed from the graphene oxide particle 100 through a freeze-drying process.

Thereafter, composite ink for a protective film may be manufactured by mixing the dried graphene oxide particle 100 from which water has been removed with the polymer resin 200 (S500). For example, the graphene oxide particle 100 and the polymer resin 200 may be mixed through a mixing process such as sonication, stirring, or milling. In this case, water being already removed from the graphene oxide particle 100 improves the dispersibility of graphene oxide particle 100 in the polymer resin 200.

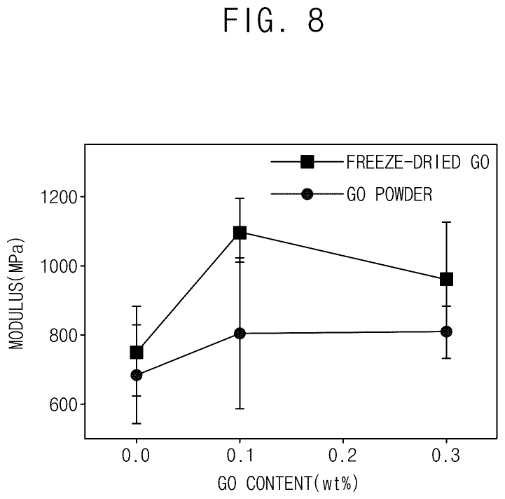

FIG. 8 shows that the Young's Modulus value of the sample (Freeze-dried GO) using the graphene oxide particle 100 whose size was adjusted to a range from about 0.1 μm to about 2 μm increased compared to the Young's Modulus value of the sample (GO powder) using a graphene oxide particle whose size was prepared to about 30 μm. In other words, by appropriately adjusting the size of the graphene oxide particle 100, the strength of the protective film can be improved.

In addition, by using a protective film mixed with the carbon nanocomposite and the polymer resin 200, the heat dissipation function of the protective film may be improved compared to the existing PET protective film.

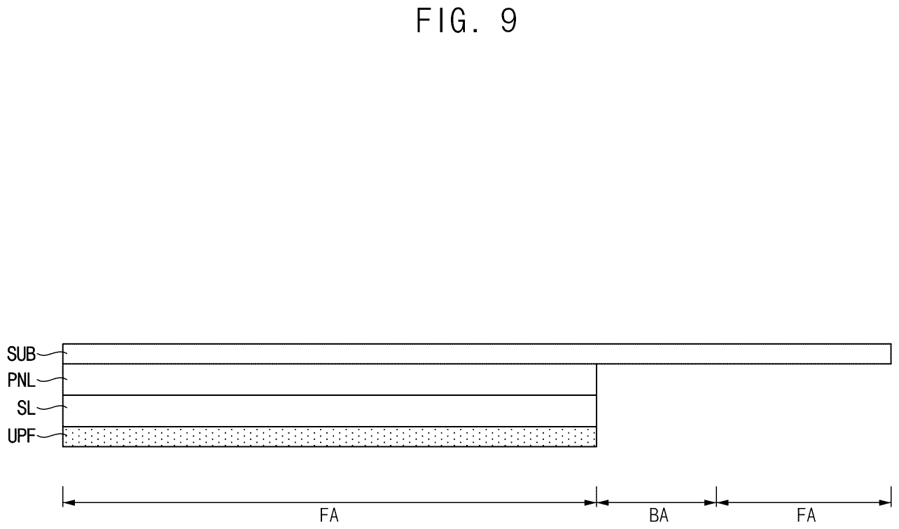

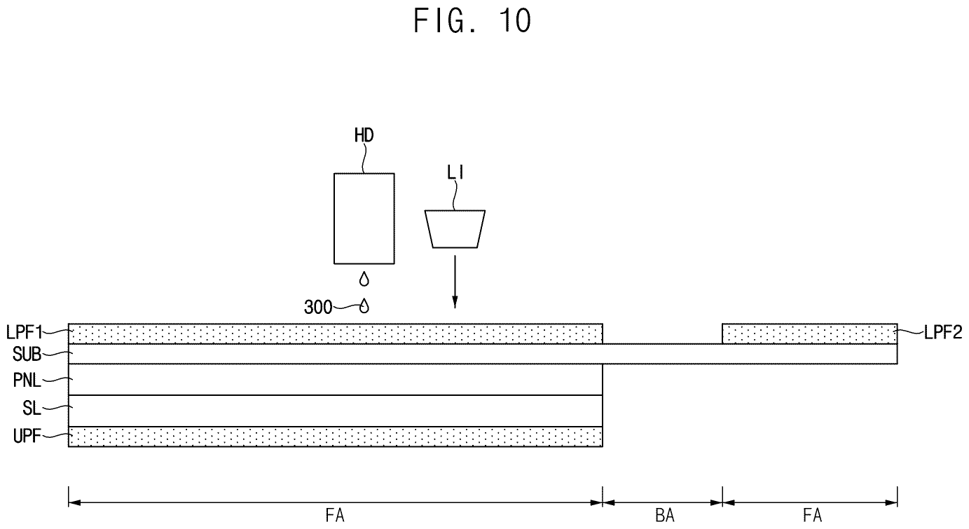

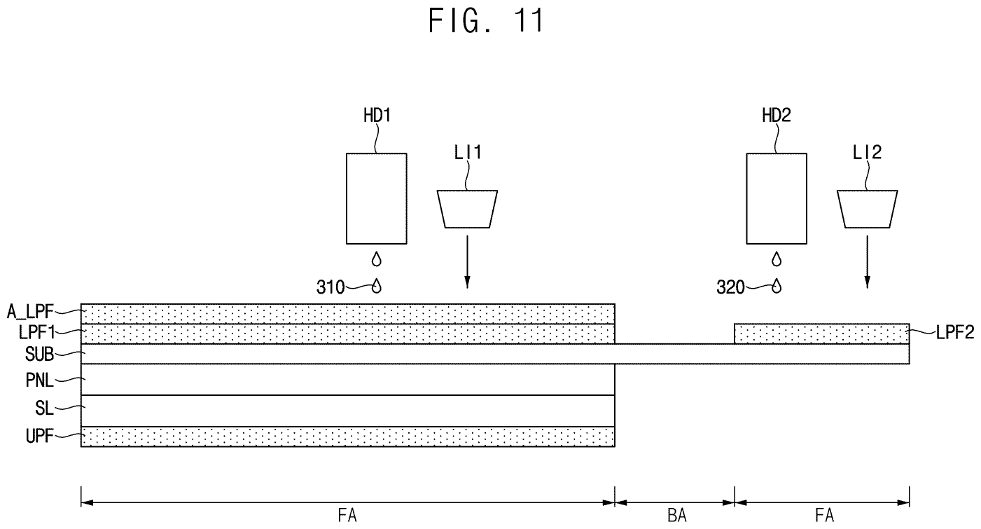

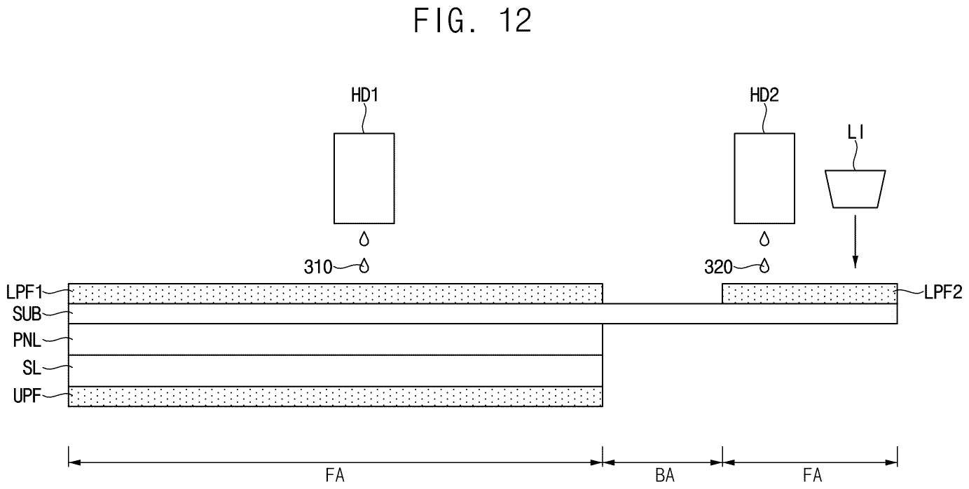

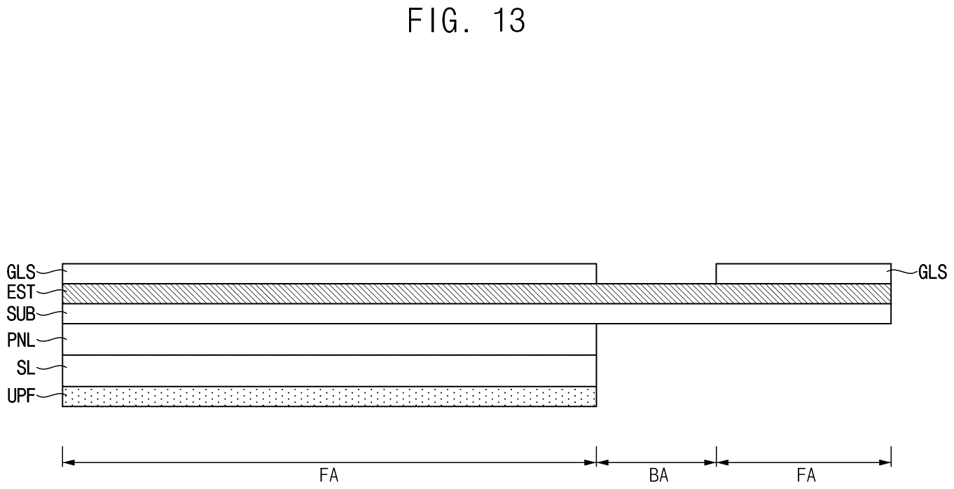

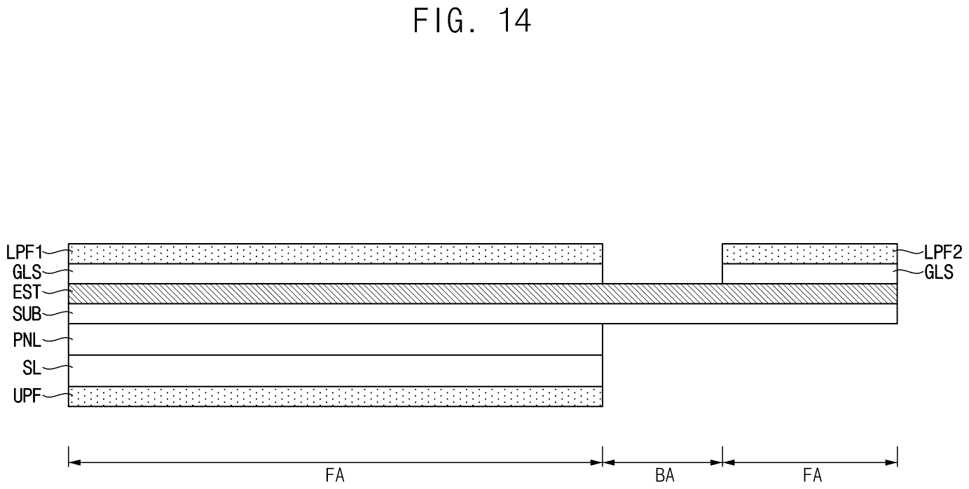

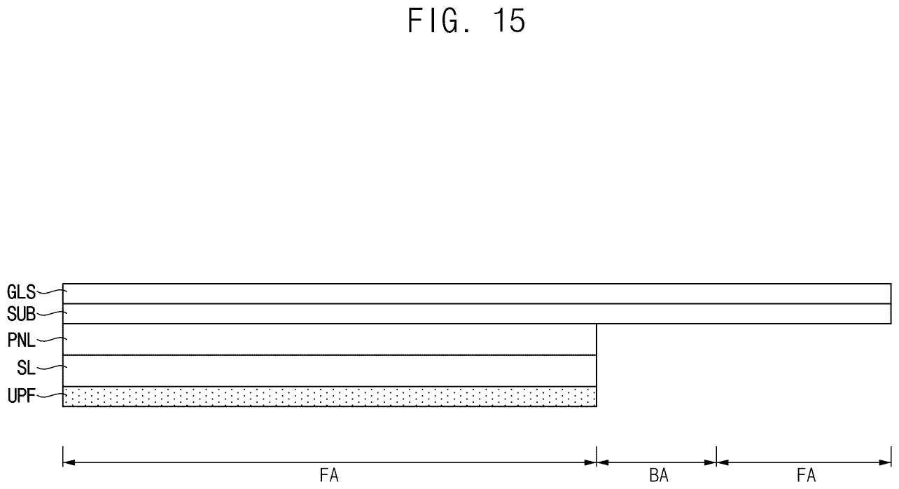

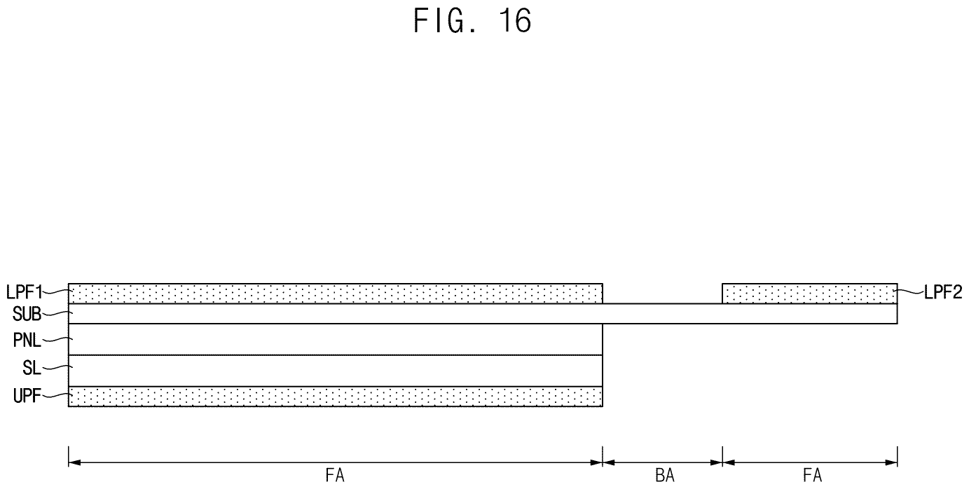

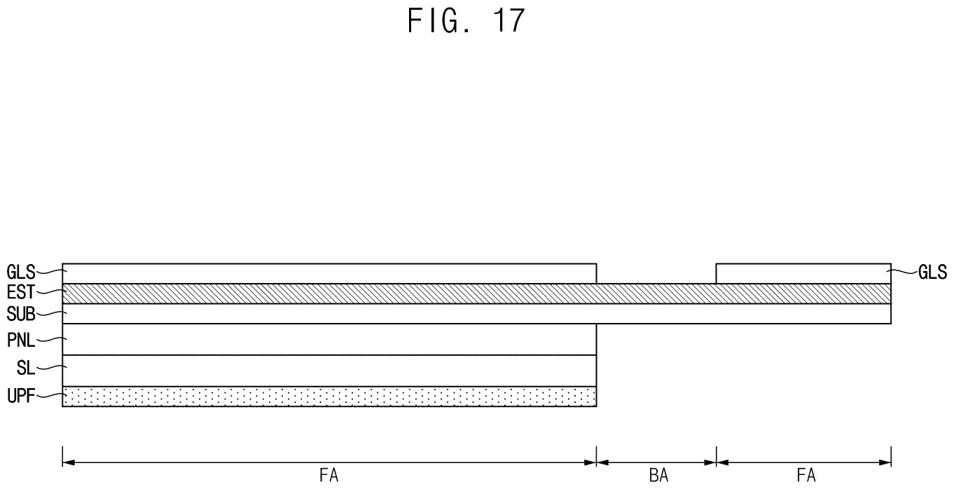

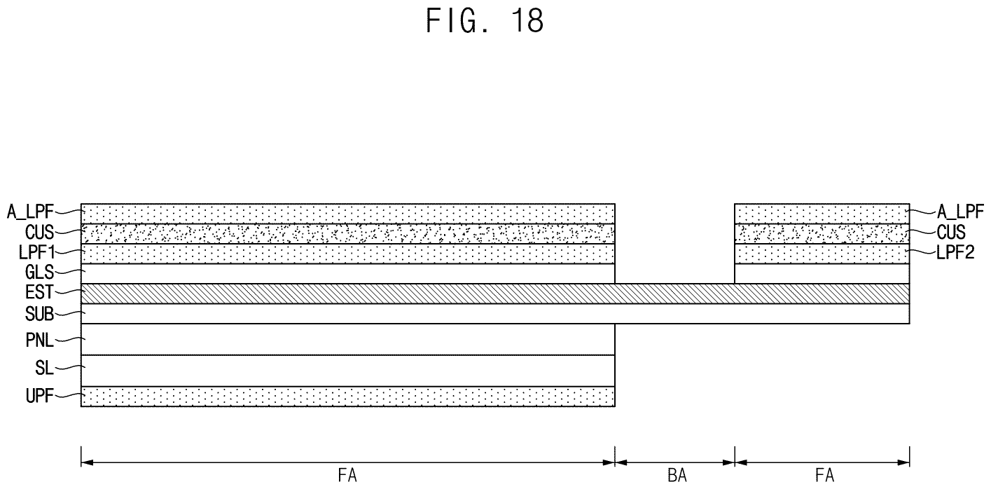

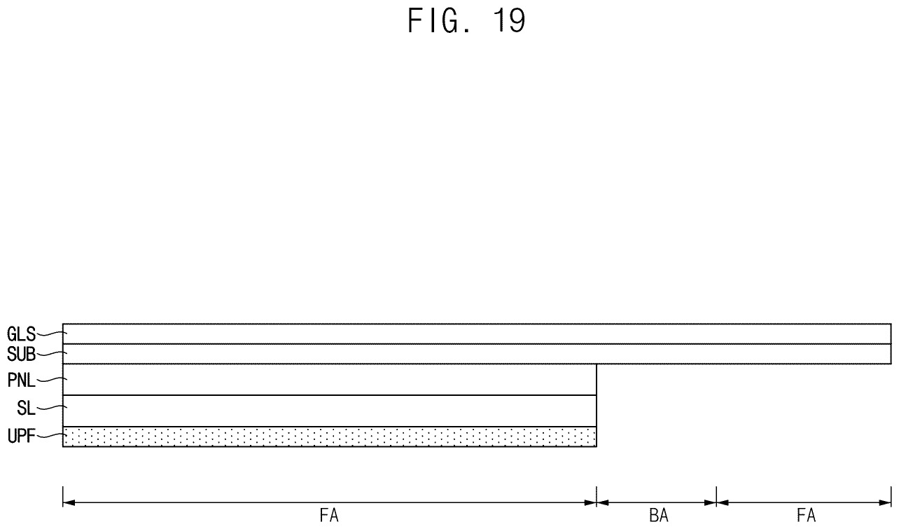

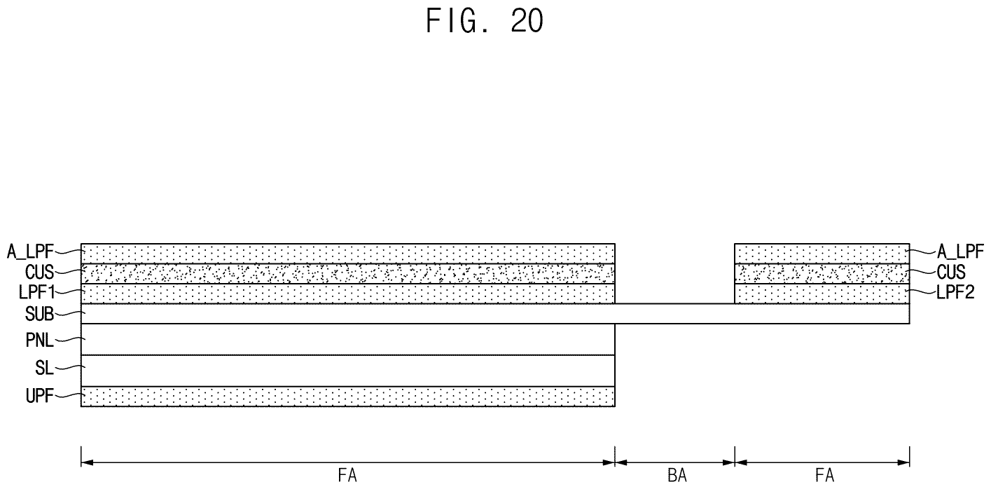

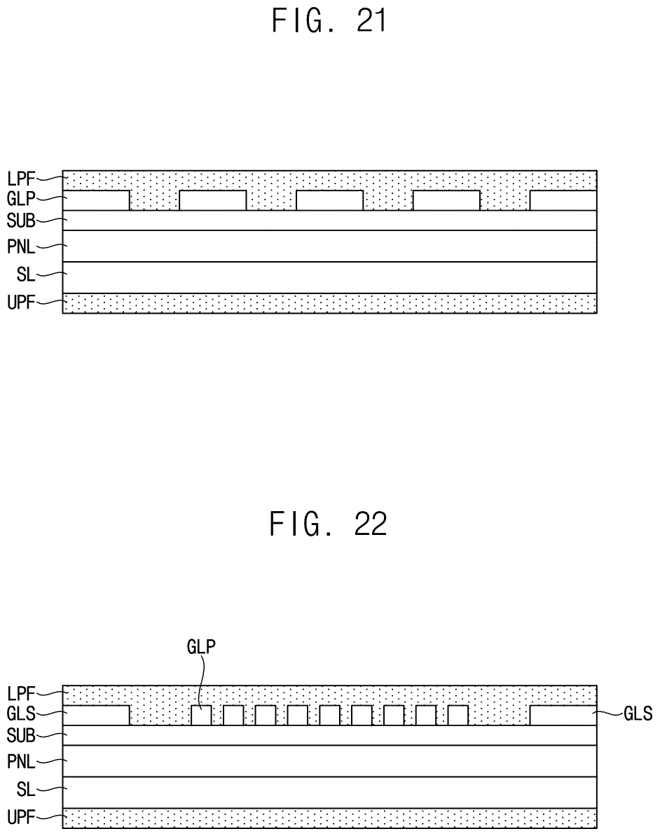

FIGS. 9 to 22 are diagrams illustrating examples in which the protective film manufactured using the method of FIG. 3 is applied. FIGS. 9 and 10 are diagrams illustrating an example of a method of manufacturing a protective film. FIG. 11 is a diagram illustrating another example of a method of manufacturing a protective film. FIG. 12 is a diagram illustrating still another example of a method of manufacturing a protective film. FIGS. 13 and 14 are diagrams illustrating still another example of a method of manufacturing a protective film. FIGS. 15 and 16 are diagrams illustrating still another example of a method of manufacturing a protective film. FIGS. 17 and 18 are diagrams illustrating still another example of a method of manufacturing a protective film. FIGS. 19 and 20 are diagrams illustrating still another example of a method of manufacturing a protective film. FIG. 21 is a diagram illustrating still another example of a method of manufacturing a protective film. FIG. 22 is a diagram illustrating still another example of a method of manufacturing a protective film.

Referring to FIGS. 9 and 10, as shown in FIG. 9, the flexible substrate SUB, the display panel PNL, the sensing layer SL, and the upper protective film UPF may be sequentially stacked and then flipped up and down. Thereafter, as shown in FIG. 10, the first lower protective film LPF1 and the second lower protective film LPF2 may be formed through an inkjet printing process using an inkjet head HD and a light irradiator L1. The inkjet head HD may discharge the above-described composite ink 300, and the light irradiator L1 may irradiate UV. The composite ink 300 may be cured by UV and may be implemented as a film.

As the protective film is formed through an inkjet printing process, the protective film may be formed in a desired area. For example, the first and second lower protective films LPF1 and LPF2 may be formed only in the flat area FA and not in the bending area BA.

Referring to FIGS. 9 and 11, a protective film with a stacked structure may be formed using a first composite ink 310 and a second composite ink 320 having different physical properties. For example, a first inkjet head HD1 for discharging the first composite ink 310, a first light irradiator LI1 for curing the first composite ink 310, a second inkjet head HD2 for discharging the second composite ink 320, and a second light irradiator LI2 for curing the second composite ink 320 may be used. In this case, after forming the first and second lower protective films LPF1 and LPF2 including the second composite ink 320, an additional lower protective film A_LPF including the first composite ink 310 may be formed to overlap the first lower protective film LPF1.

Referring to FIGS. 9 and 12, a protective film may be formed on two regions of the substrate SUB using the first composite ink 310 and the second composite ink 320 having different physical properties, respectively. For example, a first inkjet head HD1 discharging the first composite ink 310, a second inkjet head HD2 discharging the second composite ink 320, and a light irradiator L1 for curing the first and second composite inks 310 and 320 may be used. In this case, the first lower protective film LPF1 including the first composite ink 310 may be formed in the flat area FA adjacent to one side of the bending area BA, and the second lower protective film LPF2 including the second composite ink 320 may be formed in the flat area FA adjacent to the other side of the bending area BA.

Referring to FIGS. 13 and 14, as shown in FIG. 13, the display device may further include a glass substrate GLS with an etched portion. In this case, to prevent over-etching, an etch stop layer EST may be formed. Thereafter, as shown in FIG. 14, first and second lower protective films LPF1 and LPF2 may be formed on the glass substrate GLS using the above-described inkjet printing process.

Referring to FIGS. 15 and 16, as shown in FIG. 15, a glass substrate GLS for carrier substrate may be disposed. In the manufacturing process of the display device, the glass substrate GLS may be removed through laser lift off or chemical lift off. Thereafter, as shown in FIG. 16, first and second lower protective films LPF1 and LPF2 may be formed using an inkjet printing process.

Referring to FIGS. 17 and 18, as shown in FIG. 17, the display device may further include a glass substrate GLS with an etched portion. In this case, to prevent over-etching, an etch stop layer EST may be formed, similarly to the embodiment shown in FIG. 13. Afterwards, as shown in FIG. 18, a cushion layer CUS may be formed. In detail, the cushion layer CUS may be formed on the first and second lower protective films LPF1 and LPF2, and an additional lower protective film A_LPF may be formed on the cushion layer CUS. The first lower protective film LPF1, the second lower protective film LPF2, and the additional lower protective film A_LPF may perform a heat dissipation function, and the cushion layer CUS may perform a buffering function.

Referring to FIGS. 19 and 20, as shown in FIG. 19, a glass substrate GLS for carrier substrate may be disposed, similarly to FIG. 15. In the manufacturing process of the display device, the glass substrate GLS may be removed through laser lift off or chemical lift off. Thereafter, as shown in FIG. 20, first and second lower protective films LPF1 and LPF2, a cushion layer CUS, and an additional lower protective film A_LPF may be formed.

Referring to FIG. 21, in an embodiment, a plurality of glass patterns GLP may be formed on the lower surface of the flexible substrate SUB. For example, the glass patterns GLP may be formed over the entire region of the display device. the lower protective film LPF may be formed to cover the glass patterns GLP and fill the gaps between the glass patterns GLP.

Referring to FIG. 22, in an embodiment, a plurality of glass patterns GLP may be formed on the lower surface of the flexible substrate SUB. For example, the glass patterns GLP may be formed in the folding area of the display device. the lower protective film LPF may be formed to cover the glass patterns GLP and fill the gaps between the glass patterns GLP.

The protective film according to embodiments of the present invention may include a polymer resin and a graphene oxide particle whose particle size is adjusted to a preselected range. As the protective film includes both organic and inorganic materials, the heat dissipation function of the protective film may be improved, and the Young's modulus value may increase, thereby improving the strength of the protective film.

In addition, the protective film may be formed through an inkjet printing process using composite ink. Accordingly, as described above with reference to FIGS. 9 to 22, protective films of various structures can be appropriately formed.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A protective film comprising:
a photocurable resin; and
a carbon nanocomposite including a graphene oxide particle, wherein the graphene oxide particle's size is adjusted to achieve a preselected dispersibility in the carbon nanocomposite.

2. The protective film of claim 1, wherein a size of the graphene oxide particle is about 0.1 μm to about 2 μm.

3. The protective film of claim 1, wherein a weight ratio of the carbon nanocomposite is about 0.05 wt % to about 20 wt %.

4. The protective film of claim 1, wherein the carbon nanocomposite further includes carbon black.

5. The protective film of claim 1, wherein the photocurable resin is cured by light and has a viscosity of about 10 cPS to about 500 cPS.

6. A display device comprising:
a lower protective film including a photocurable resin and a carbon nanocomposite, wherein the carbon nanocomposite includes a graphene oxide particle;
a flexible substrate disposed on the lower protective film;
a transistor layer disposed on the flexible substrate; and
an emission layer disposed on the transistor layer.

7. The display device of claim 6, wherein a size of the graphene oxide particle is about 0.1 μm to about 2 μm.

8. The display device of claim 6, wherein the flexible substrate comprises:
a flat area having a first flat area and a second flat area, and
a bending area between the first flat area and the second flat area,
wherein the lower protective film overlaps the flat area and does not overlap the bending area.

9. The display device of claim 6, further comprising:
a plurality of glass patterns disposed under the flexible substrate,
wherein the lower protective film covers the glass patterns.

10. A method of manufacturing a display device, the method comprising:
forming a protective film;
forming a display panel on a flexible substrate; and
forming the protective film under the flexible substrate,
wherein the forming the protective film includes:
preparing a graphene oxide particle in powdered state;
adjusting a size of the graphene oxide particle; and
forming a composite ink by mixing the size-adjusted graphene oxide particle with a photocurable resin.

11. The method of claim 10, wherein a size of the graphene oxide particle is adjusted to a range from about 0.1 μm to about 2 μm.

12. The method of claim 10, wherein a size of the graphene oxide particle in powdered state is about 20 μm to about 40 μm.

13. The method of claim 10, further comprising:
dispersing a powdered graphene oxide particle in water.

14. The method of claim 13, wherein a size of the graphene oxide particle dispersed in water is about 5 μm to about 15 μm.

15. The method of claim 10, wherein a size of the graphene oxide particle is adjusted by sonication of the graphene oxide particle.

16. The method of claim 10, further comprising:
removing water from the size-adjusted graphene oxide particle.

17. The method of claim 10, wherein the protective film includes a first lower protective film and a second lower protective film that have a different physical property from each other,
wherein the first lower protective film is formed by ejecting a first composite ink from a first inkjet head, and
wherein the second lower protective film is formed by ejecting a second composite ink having different physical properties from the first composite ink from a second inkjet head.

18. The method of claim 17, wherein the first lower protective film and the second lower protective film overlap each other with the flexible substrate in a bent state.
